(19) United States
(12) Patent Application Publication
(10) Pub. No.: US 2015/0022807 A1
(43) Pub. Date: Jan. 22, 2015

(54) UNIVERSAL SAMPLE HOLDER

(71) Applicant: ECOLE POLYTECHNIQUE FEDERALE DE LAUSANNE (EPFL), Lausanne (CH)

(72) Inventor: Graham Knott, Bougy-Villars (CH)

(21) Appl. No.: 14/384,770

(22) PCT Filed: Mar. 12, 2013
(86) PCT No.: PCT/IB2013/051933

§ 371 Date: Sep. 12, 2014

(30) Foreign Application Priority Data
Mar. 12, 2012 (IB) PCT/IB2012/051160

(51) Int. Cl. G01N 21/01; H01J 37/26

(52) U.S. Cl. CPC G01N 21/01; H01J 37/261
USPC 356/244

(57) ABSTRACT

This device is for holding samples during their preparation prior to imaging in the electron microscope. The design means it can be transferred between the light and electron microscopes as well as trimming devices used to prepare the final sample. It can also be used at both ambient and cryo temperatures down to −110° C. The device consists of a base plate that can be held on the stage of a light microscope. It has an aperture through which transmitted light can pass. In this aperture is a clamp which holds a small transparent plastic sphere; the sample sphere. The sample for preparation is bonded to this sphere. The shape of this clamp and sphere means that the sample can be held at any angle to allow for optimal imaging in any light microscope and in the trimming devices, including the ultramicrotome. Once trimmed, the entire universal sample holder can then be transferred into the scanning electron microscope, or held in the ultramicrotome for thin sectioning.

### FIELD OF INVENTION

The present invention relates to the handling of biological samples. It more precisely refers to sample holders which are used for visualizing the samples, for instance for light microscopy and electron microscopy.

### STATE OF THE ART

Electron microscopy is employed with increasing frequency in the field of life sciences to image cells and tissues at high resolution. With its high resolution and ability to see all macromolecular complexes it is the only technique that allows biologists to explore the complex architecture within biological systems. For preparing the samples for EM, there are a multitude of different preparation techniques. This includes ambient temperatures techniques for samples that are typically embedded in resin, and cryo techniques (−50 to −90° C.) for hydrated samples. In most cases the samples (cells and tissues) need to be significantly reduced in size, and the correct region of the sample located so that the region of interest can eventually be imaged.

Today there are a range of different of electron imaging systems for visualising biological samples. These are either thin sectioning approaches where the sample is sliced very thinly and then imaged with electrons, or block face scanning techniques, where the block itself, containing the sample, is imaged with a scanning electron beam. Both approaches also allow for the sample to be imaged serially so that information be collected at different depths for volumetric information to be obtained. In all cases, it is critical how the sample is mounted, in a very stable system, and also at the correct angle.

With the increase in the use of different forms of light microscopy, including super resolution techniques and electron microscopy is being demanded ever more frequently to also image the same regions of a biological sample that were imaged with light. This technique of correlated light and electron microscopy requires samples to be prepared with a very high degree of accuracy and reliability. Typically, the region imaged in the light microscope is within a small part of a single cell, with a size range of just a few microns. Imaging this same region with electron microscopy is both time consuming and requiring a great deal of skill. Currently there are a number of different protocols for carrying this out, all have advantages and disadvantages.

Irrespective of the final imaging method, the preparation part is the same. The biological sample is firstly immobilized or fixed, with either chemicals or freezing, and then embedded in a resin. This resin block is then manipulated into the correct position and trimmed with very accurate cutting devices so that the region of interest can be sectioned at the right position. During this entire process a clear view of the sample is needed. Currently, this involves using light microscopes for imaging the sample within the resin. Typically the sample block is placed on a glass slide and imaged with transmitted light, and then mounted into a standard holder and trimmed either by hand with either a razor blade or a glass knife with an ultramicrotome. This repeated imaging and trimming process takes many hours, and each time the block is put back into the ultramicrotome the correct angle needs to be carefully adjusted so that the cutting angle of the knife is the same each time. The block also needs to be small and transparent so that it can be easily seen using the transmitted light in the microscope.

### GENERAL DESCRIPTION OF THE INVENTION

The sample holder according to the present invention substantially differs from the state-of-the-art by allowing the sample to be held at any angle for optimal viewing in the light microscope, as well as in the chamber of a scanning electron microscope and also on the cutting arm of the ultramicrotome.

The invention more precisely refers to a sample holder and its use as defined in the independent claims.

Preferred embodiments of the invention are defined in the dependent claims.

With the sample holder of the invention there is no need to remove the sample and place it onto another holder. The angle of the sample can be changed by rotating the transparent sphere. The sphere may be held in place by two near half cups that can be pushed together by means of a single screw. Below this transparent sphere is advantageously an aperture through which light can pass. This gives the best opportunity to view the sample through the sphere, when held in the clamp.

The invention is preferably used to hold samples while they are being prepared and imaged in both the light and electron microscopes. It can also be used in trimming devices used to prepare samples for electron microscopy. The holder makes it possible for samples to be viewed at any angle with the light microscope, by providing a direct light path through the holder and the sample. The invention therefore make it possible to prepare and view a sample without having to remove it from the sample holder.

The holder will eliminate the need for un-mounting and remounting the sample, and repositioning. The sample will be mounted in the same holder throughout imaging and preparation. The sample holder is designed to be used at room temperature as well as temperatures to around −110° C. This will enable frozen samples can be prepared for cryo electron microscopy.

To achieve this the invention may advantageously comprise a transparent sphere, a clamp for holding the sphere, and a baseplate that has an aperture for allowing light to pass. The spheres are flattened on two opposite sides. These are made from a transparent colourless resin that can also be milled or trimmed if necessary. The flattened sides are both the same size and are approximately 1 mm in width. The reason for the flattened sides are: to provide a flat surface onto which the sample can be bonded, but also an optically flat surface on the opposite side so that parallel light is not distorted when imaged in the light microscope. The spheres will be of different sizes from 3 to 6 mm in diameter, depending on the type of sample.

The spheres to which the sample is bonded can be placed directly into specially designed cell culture wells. This enables cells, imaged live in the light microscope to be processed and then directly attached to the sample sphere without any intermediate steps to locate the cell of interest. In this situation the entire well is attached to the sphere to be trimmed later in the ultramicrotome.

The clamp part of the invention comprises two metal cups that hold the sample sphere. These metal cups are half cone shaped and sit on the base plate, either side of the sphere. They hold the sphere tightly in place. There is a spherical recess on the inner surface of each piece of the clamp into which the sphere can sit. However when clamping the sphere the two halves leave a significant gap. This gap is useful for allowing the sample to be orientated at 90° to the imaging plane, so that it can then be viewed, in the light microscope, from the side.

The clamping part is attached to a base plate. One side of the clamp is fixed statically to the base plate and cannot be moved, the other half can move across the base plate to increase or decrease the distance to the other half of the clamp. This will be achieved by a locking bolt. Loosening this bolt will allow the sample sphere to be introduced into the recesses and locked into place. It will also allow the sphere's orientation to be altered, by decreasing the force with which the bolt is holding the sphere. The movement of this lock bolt will be very precise so that when loosened the sample sphere can be reoriented, but will not be fall from the clamp.

The position at which the sphere is held is important for the operation of the device. The sphere will be held in place in the clamp so that just under half of the sphere is protruding from above the clamp. This means that the sample, which is bonded to one of the two flat sides of the sphere, is held clear of the clamp, and is easily accessible. It also means that changing the sample sphere's orientation in the clamp can alter the angle of the sample.

In the centre of the base plate is an aperture. This aperture is positioned below the sample sphere, in the centre below the two clamps. This allows light to pass through the base plate and through the sample sphere to illuminate the sample that is bonded to its top surface.

The sample holder can be placed onto the stage of any light microscope, the cutting arm of any ultramicrotome, and stage of any scanning electron microscope. This will be achieved by using plates with recesses, into which the sample holder will fit. There will be one that holds the sample holder on the stage of a light microscope; one that holds the sample holder onto an ultramicrotome; and one that holds it onto the stage of any scanning electron microscope. The light microscope holder has the same dimensions as a standard histology glass slide (25×75×1 mm) except that in its centre there is a recessed hole into which the sample holder can sit and through which light can pass. This ‘slide mount’ enables the sample holder to be held in place in the standard slide clamping system of any light microscope stage so that it can be moved laterally in the x and y direction, and up and down with the focus knob, in the z direction.

The ‘slide mount’ is, however, not an integral part of the universal sample holder and is not essential for its operation. It is an additional part of the device that helps the sample holder to be positioned in the light microscope so that light can pass through the sample, therefore illuminating it, and without light having to pass through any other medium. It will give the illuminating light a free path to the sample sphere.

For the universal sample holder to be held on the arm of any ultramicrotome, the base plate is designed to fit precisely onto a modified metal stub. The stem of this stub fits into any of the ultramicrotomes available on the market (Leica, Reichert, RMC). The attachment of the sample holder to this stub is with a clamping device that locks the holder in place.

This attachment of the universal sample holder, to the plate that is held on the arm of the ultramicrotome, ensures that the sample can be kept in exactly the same orientation each time it is removed and replaced. This ensures that when the sample is being trimmed, its position in the holder will not change after it is removed and replaced in the light microscope for viewing.

### DETAILED DESCRIPTION OF THE INVENTION

The invention will be better understood with some non-limiting illustrated examples

FIG. 1 shows an exploded side view of the parts that make up the universal sample holder: sample sphere, clamp, base plate and locking bolt. Also visible is the hole in the base plate to allow the light to pass through the sample sphere uninterrupted. The scale indicates the approximate width of the base plate as 3.0 cm. The diameter of the sample sphere is between 3.0 and 6.0 mm.

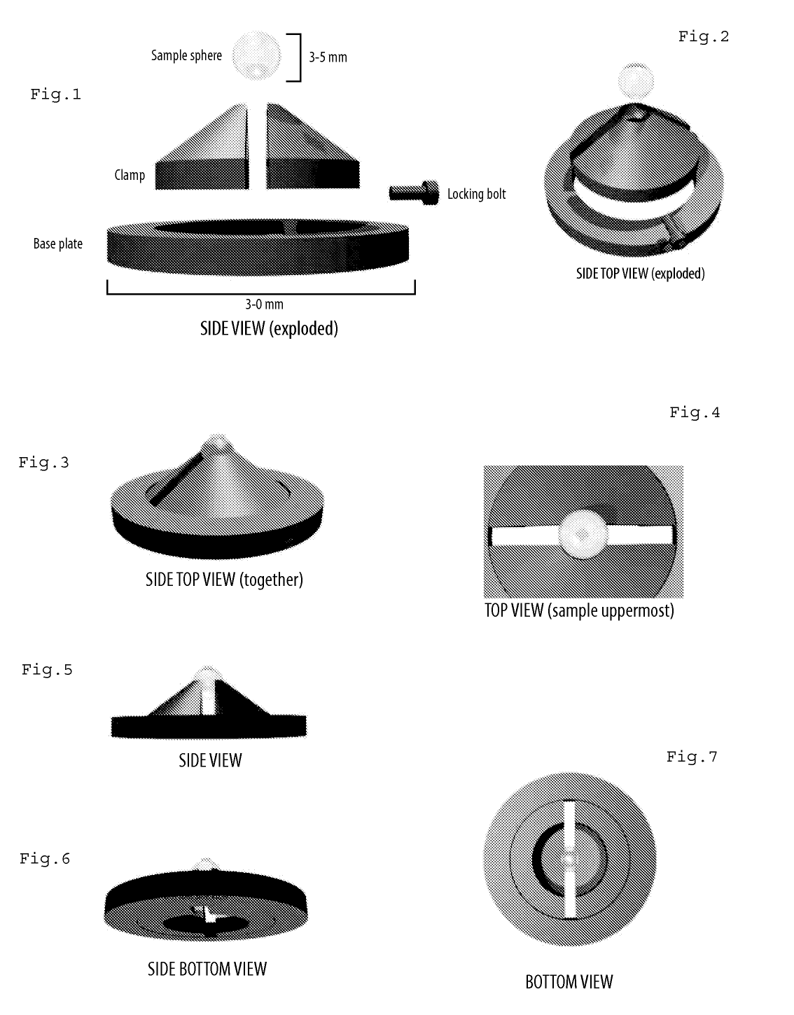

FIG. 2 shows an exploded side view and the recess into which the sample sphere sits, with the sample sphere above.

FIG. 3 represents a side view of the universal sample holder, assembled, with a resin embedded sample on the uppermost surface of the sample sphere.

FIG. 4 is a top view close up of the sample sphere with a resin sample bonded in place. The sample sphere is lying uppermost on the sample sphere that allows visibility of the sample from the top.

FIG. 5 is a side view of the universal sample holder showing the position of the sample sphere to the base plate.

FIG. 6 represents a below side view of the universal sample holder showing the aperture in the base plate to allow the light access to the sample sphere.

FIG. 7 represents a bottom view for the universal sample holder viewed through the aperture in the base plate with the sample sphere clamped in place.

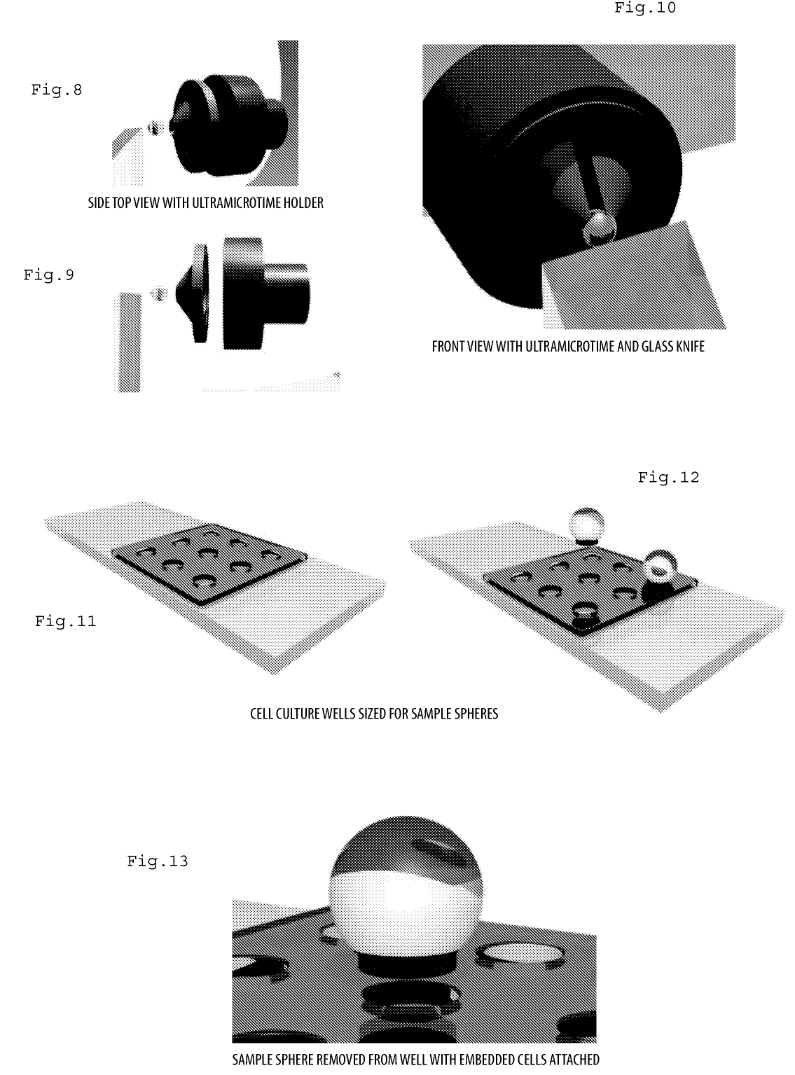

FIG. 8 is a side view of the universal sample holder separated from the sample sphere, and separated from the microtome stub that holds it in place in any standard ultramicrotome.

FIG. 9 is a side view of the universal sample holder, the microtome stub, and the sample sphere.

FIG. 10 is a view from above of the universal sample holder attached with the ultramicrotome stub and with a glass knife in place. In this configuration the sample, bonded to the sample sphere, can be cut with the glass knife (or diamond knife) as the ultramicrotome arm is moved up and down.

FIG. 11 shows a culture plate with nine wells in which cells can be grown and imaged with light microscopy. These wells are sized to fit the sample sphere. When electron microscopy is needed, the entire culture plate can be processed and the sample sphere bonded to the cells with resin that is poured into the well. Once hardened, the sample sphere is removed with the resin in place, containing the cells of interest.

FIG. 12 shows a culture plate with two sample spheres, viewed from the side.

FIG. 13 represents a single sample sphere, viewed from the side, after being lifted from the culture well, with the resin embedded cells attached to the underside.

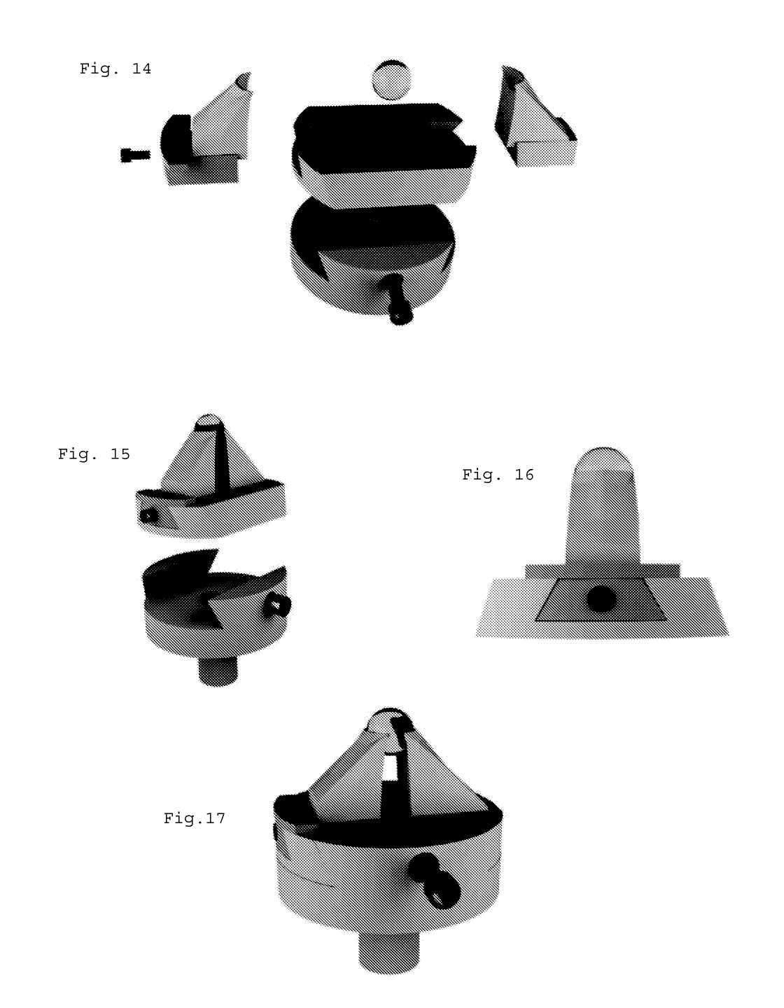

FIG. 14 Exploded side view of sample holder, including the sample sphere, and holder (lower part) for the ultramicrotome.

FIG. 15 Above, side view of the sample holder assembled (upper part) and ultramicrotome holder (lower part), with sample sphere clamped in holder.

FIG. 16 Side view of sample holder showing the position of the sample sphere position when clamped in place.

FIG. 17 Above side view of sample holder assembled, together with the ultramicrotome holder, and the sample sphere clamped in place.

It must be understood that the examples of the invention provided here, the phraseology and terminology, are for the purposes of description and should not be regarded as limiting.

1. A sample holder for visualizing biological samples comprising a removable support including at least one contact surface adapted to be in contact with a sample or an embedded sample;
characterized by the fact that said removable support is a transparent sphere.

2. The sample holder according to claim 1 wherein the sphere diameter is comprised between 3 and 6 mm.

3. The sample holder according to claim 1 wherein said contact surface is a first flattened portion located on one side of the sphere.

4. The sample holder according to claim 3 wherein said sphere comprises a second flattened portion, located on a side of the sphere which is opposite with respect to said contact surface.

5. The sample holder according to claim 4 wherein each flattened portion is approximately 1 mm wide.

6. The sample holder according to claim 1 wherein the sphere is rotatable.

7. The sample holder according to claim 6 comprising clamping means adapted to hold the sphere.

8. The sample holder according to claim 7 wherein said clamping means comprise locking means, for instance a locking bolt, which is adapted to lock the sphere rotation.

9. The sample holder according to claim 7 wherein said clamping means comprises two half cone-shaped cups.

10. The sample holder according to claim 9 wherein said cups are movable with respect to each other but can be maintained at a fixed distance from each other, by activation of said locking means.

11. The sample holder according to claim 7, comprising a baseplate adapted to hold said clamping means and which has an aperture adapted to let light pass through.

12. The sample holder according to claim 1 comprising a slide mount.

13. Use of a sample holder as defined in claim 1 comprising the following steps:
preparing a sample embedded in a resin suitable for electron microscopy;
fixing said resin onto said contact surface;
clamping said sphere;
imaging said sphere and attached sample with transmission light microscope; and
locking, rotating and trimming the sphere to such an extent that the sample can be efficiently visualized, with light and scanning electron microscopy while remaining fixed at all times in the sample holder.
